(19) United States
(12) Patent Application Publication
(10) Pub. No.: US 2018/0227680 A1
(43) Pub. Date: Aug. 9, 2018

(54) Acoustic Power Coupling for Mobile Audio Devices

(71) Applicant: QUALCOMM Incorporated, San Diego, CA (US)

(72) Inventors: Linda Irish, San Diego, CA (US); William Henry Von Novak, III, San Diego, CA (US); Cody Wheeland, San Diego, CA (US)

(21) Appl. No.: 15/427,120

(22) Filed: Feb. 8, 2017

(51) Int. Cl. H04R 25/00; H04R 1/10; H04R 9/06; H03F 3/217; H03F 3/185

(52) U.S. Cl. CPC H04R 25/554; H04R 1/1025; H04R 1/1016; H04R 9/06; H03F 2200/03; H03F 3/185; H04R 2225/023; H04R 2225/31; H04R 2420/01; H03F 3/2173

(57) ABSTRACT

Techniques for acoustic power coupling for mobile audio devices are described. In one or more implementations, a mobile audio device includes a device speaker with a membrane that produces audio output for the mobile audio device, an amplification circuit electrically connected to the device speaker, and a rechargeable battery electrically connected to the amplification circuit. In response to a deformation of the membrane by a force supplied by a force generator, an alternating (AC) voltage is produced on the amplification circuit. The amplification circuit optionally amplifies the AC voltage and converts the AC voltage to a direct (DC) voltage. The amplification circuit applies the DC voltage to the rechargeable battery to recharge the rechargeable battery.

### TECHNICAL FIELD

This disclosure relates generally to an acoustic battery charging system for wireless charging of audio devices. The charger provides an acoustic signal to the speaker of the device to be charged. The acoustic signal vibrates the speaker membrane, producing a voltage back across an amplification circuit that drives the speaker. The produced voltage is used to charge the device battery.

### BACKGROUND

Small mobile audio devices have become more popular in the market. Examples include hearing aids that can be inserted entirely or almost entirely in the ear canal, such as completely-in-canal (CIC) hearing aids, wireless earbuds, and devices for health monitoring and fitness tracking. These devices are mostly invisible to an outside observer and are very portable, fitting easily into a pocket or a small handbag.

Smaller devices though, however convenient and useful, come with their own disadvantages. For example, these devices are often powered by rechargeable batteries because, like the devices themselves, the batteries are quite small and replacing them can be difficult. There are several ways to charge the batteries of small mobile audio devices, including wired chargers and contact chargers. Smaller devices, however, are difficult to connect to wired chargers and the connectors take up valuable space in the device. Further, devices worn in the ear canal for longer time periods (like CIC hearing aids) tend to pick up oils, ear wax, and dirt, making contact charging more difficult.

Wireless charging techniques can be used as well, but typically require extra components in the hearing aid (e.g., coils, ferrites, and dedicated charging circuitry), which again take up valuable space in a small device. All of these charging methods can be annoying to users, and can reduce the perceived usability of a device.

### SUMMARY

Techniques for acoustic power coupling for mobile audio devices are described. In one or more aspects, a mobile audio device includes an amplification circuit electrically connected to a rechargeable battery configured to power the mobile audio device, and a device speaker electrically connected to the amplification circuit. The device speaker includes a membrane configured to deform in response to a signal from the amplification circuit to produce audio output for the mobile audio device. In response to a deformation of the membrane caused by a force from a force generator, an alternating (AC) voltage is produced on the amplification circuit. The amplification circuit optionally amplifies the AC voltage and converts the AC voltage to a direct (DC) voltage. The DC voltage is applied to the rechargeable battery effective to recharge the rechargeable battery.

In other aspects, methods and systems for providing acoustic power coupling for mobile audio devices are described. A force generator is configured to generate a force. A charging receptacle is configured to receive the mobile audio device and orient the mobile audio device to present a speaker membrane of the mobile audio device to receive the force. The charging receptacle further provides a seal between the exterior of the mobile audio device and the interior of the charging receptacle that enables efficient energy transfer from the force generator to the membrane.

In still other aspects, a mobile audio device includes a first means that is electrically connected to a rechargeable battery configured to power the mobile audio device. The first means is configured for sending, receiving, and modifying signals between components of the mobile audio device, and a second means electrically connected to the first means. The second means is configured to deform in response to a signal from the first means to produce audio output for the mobile audio device. In response to an external force, the second means is configured to deform and produce an AC voltage across the first means. The first means is further configured to convert the AC voltage to a DC voltage and apply the DC voltage to the rechargeable battery.

### BRIEF DESCRIPTION OF DRAWINGS

The details of various aspects are set forth in the accompanying figures and the detailed description that follows. In the figures, the left-most digit(s) of a reference number identifies the figure in which the reference number first appears. The use of the same reference numbers in different instances in the description and the figures may indicate similar or identical items. Entities represented in the figures may be indicative of one or more entities and thus reference may be made interchangeably to single or plural forms of the entities in the discussion.

FIG. 1 illustrates an example mobile audio device in which techniques for acoustic power coupling for mobile audio devices can be implemented.

FIG. 2 illustrates additional details of the device speaker illustrated in FIG. 1

FIG. 3 illustrates an example amplification circuit that is operable to enable techniques for acoustic power coupling for mobile audio devices in accordance with one or more aspects.

FIG. 4 illustrates another example amplification circuit that is operable to enable techniques for acoustic power coupling for mobile audio devices in accordance with one or more aspects.

FIG. 5 illustrates an example flow chart illustrating an example process for implementing acoustic power coupling for mobile audio devices in accordance with one or more aspects.

FIG. 6 illustrates an example charging system in which techniques for acoustic power coupling for mobile audio devices can be implemented.

FIG. 7 is a block diagram that illustrates another example charging system generally, including an example mobile audio device that is representative of one or more systems and/or devices that may implement the various techniques described herein.

### DETAILED DESCRIPTION

### Overview

Small mobile audio devices (e.g., Bluetooth™ earbuds, health monitors, fitness trackers, completely-in-canal (CIC) hearing aids and so forth) are becoming a popular and useful segment of the audio device market. They provide a discreet and portable way to listen to audio media or improve hearing. Because of their small size and the related difficulty of trying to replace batteries, these devices often use rechargeable batteries, which can present challenges with respect to keeping the battery charged. While these devices can be charged using wired chargers, contact chargers, and wireless chargers, each of these methods presents its own problems. Smaller devices are difficult to connect to wired chargers and require connectors that take up valuable space in such small devices. Additionally, devices that are worn in the ear canal may pick up oils, ear wax, and dirt, making contact charging less reliable and more difficult. Wireless charging also typically requires extra components in the device, again taking up valuable space. All of these charging methods can be annoying to users, and can reduce the perceived usability of a device.

To address these problems, techniques for acoustic power coupling for mobile audio devices are described. For example, in a mobile audio device that is worn in the ear canal, the device sends sound to the wearer's eardrum using a speaker. In general, there are two kinds of speakers used in small devices—voice coil speakers and piezoelectric speakers. Voice coil speakers operate by passing current through a coil attached to a membrane, which generates a magnetic field. The magnetic field interacts with a magnet, and moves the membrane back and forth, generating pressure waves. The second kind of speaker is a piezoelectric speaker. It has a crystal that deforms when a voltage is placed across it. The crystal is coupled to a membrane that moves back and forth with the deformation of the crystal, again generating pressure waves. At frequencies between roughly 20 Hertz (Hz) and 20 kilohertz (KHz), the pressure waves are heard as sound. In either case, if the membrane is moved mechanically (e.g., by exposing the membrane to high-frequency sound waves), the reverse happens—the coil moves around the magnet (or the crystal is deformed) and a voltage is produced on the coil (or crystal). Thus, the same components that produce the sound can produce a voltage that may be used to charge the battery.

By way of example, consider a CIC hearing aid that includes a class-D amplifier to drive the speaker and produce sound. Using the described techniques and devices, the same class-D amplifier can be used to convert an alternating (AC) voltage, produced by moving the membrane, into a direct (DC) voltage that can be applied to charge the battery. In various implementations, other amplifier configurations can also be used to convert a force applied to the speaker of a mobile audio device to provide a charge to the battery that powers the device.

### Example Device

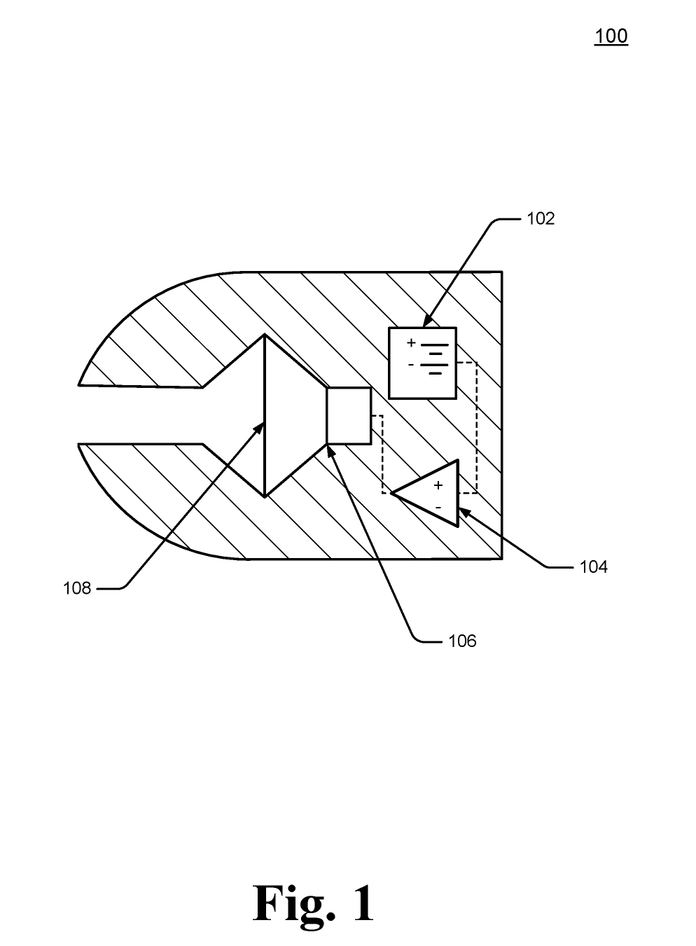

FIG. 1 illustrates an example mobile audio device 100 in which techniques for acoustic power coupling for mobile audio devices can be implemented. The example mobile audio device 100 includes a rechargeable battery 102 that powers the mobile audio device 100, an amplification circuit 104 that is electrically connected to the rechargeable battery 102, and a device speaker 106 that is electrically connected to the amplification circuit 104. The device speaker 106 includes a membrane 108. The membrane 108 can be made from a variety of flexible materials (e.g., natural fibers, synthetic fibers, paper-based materials, plastic, metals, and so forth). The example mobile audio device 100 can be any of a variety of battery-powered audio output devices (e.g., a hearing aid, a wireless earbud, and so forth). The rechargeable battery 102 can be any of a variety of battery types (e.g., nickel-metal hydride, lithium ion, lithium ion polymer, and so forth).

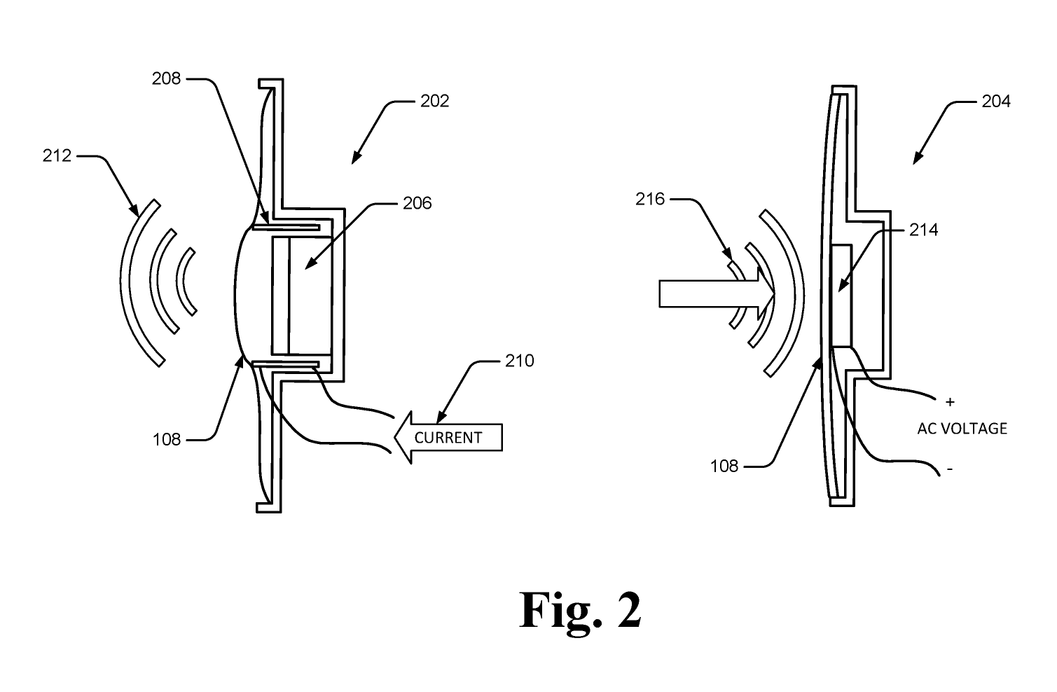

The membrane 108 deforms in response to a signal received from the amplification circuit 104, which produces audio output for the mobile audio device 100 in the form of sound pressure waves. Additionally, the membrane 108 can also deform in response to an applied force (e.g., a sound pressure wave, a vibration force, and so forth), which produces an alternating (AC) voltage on the amplification circuit 104. The amplification circuit 104 is configured such that when the AC voltage is presented to the speaker-drive outputs of the amplification circuit 104, the AC voltage is rectified to a direct (DC) voltage, and the DC voltage is applied to the rechargeable battery 102. Additional details and features of the amplification circuit 104 and the device speaker 106 are described in FIGS. 2, 3, and 4.

FIG. 2 illustrates example device speakers 202 and 204. The example device speaker 202 is a voice coil speaker. The example device speaker 202 includes a magnet 206, a coil 208, and a membrane 108. The coil 208 is attached to the membrane 108. An alternating current 210 is applied to the coil 208, which generates a magnetic field. As the magnetic field alternates with the current 210, the coil 208 and the attached membrane 108 are alternately repelled and attracted by the magnet 206, causing the membrane to move back and forth. The back and forth motion creates sound pressure waves 212. The example device speaker 204 is a piezoelectric speaker. The example device speaker 204 includes a piezoelectric plate 214 and a membrane 108. The piezoelectric plate 214 can be made from any of a variety of materials that exhibit the piezoelectric effect (i.e., materials that deform when a voltage is applied), including synthetic crystals (e.g., langasite or lithium niobate), synthetic ceramics (e.g., lead zirconate titanate or sodium tungstate), and so forth. By a process similar to that described for the coil 208 of example device speaker 202, an AC voltage can be applied to the piezoelectric plate 214, causing it to deform and move the membrane 108 back and forth to produce sound.

The processes to produce sound described above are reversible. Consequently, the membranes 108 of example speaker 202 or of example speaker 204 can be mechanically moved by application of a force to produce an electrical signal. The force can be applied by various mechanisms. In some implementations, the force is a pressure wave applied from a distance away from the membrane 108. In other implementations, the force may be applied by an object making physical contact with the membrane 108 (e.g., a piston or a vibration plate). In implementations in which the force is a pressure wave, the pressure wave may be an ultrasonic pressure wave (i.e., have a frequency above 20 kilohertz (KHz)). In other implementations, the frequency of the pressure wave may be at or below 20 KHz. The magnitude of the force may also vary, depending on the configuration of the device speaker 106 and the amplification circuit 104. In some implementations, the magnitude of the force is at least 0.5 Pascals (Pa).

Continuing the example shown in FIG. 2, the membrane 108 of the example speaker 204 can be exposed to a high-frequency pressure wave 216, causing the membrane 108 to move back and forth, deforming the piezoelectric plate 214 and thereby producing an AC voltage. Similarly, the membrane 108 of the speaker 202 can be exposed to a force that moves the membrane 108 and the coil 208 around the magnet 206. This motion causes an alternating current to flow and produces an AC voltage across the coil 208. In both of the example speaker configurations 202 and 204, applying force to the membrane 108 produces and AC voltage that can be processed by the amplification circuit 104 and used to charge the rechargeable battery 102. These techniques thereby allow the same mechanism that produces sound output for a mobile audio device to generate power that can be used to charge the battery of the mobile audio device.

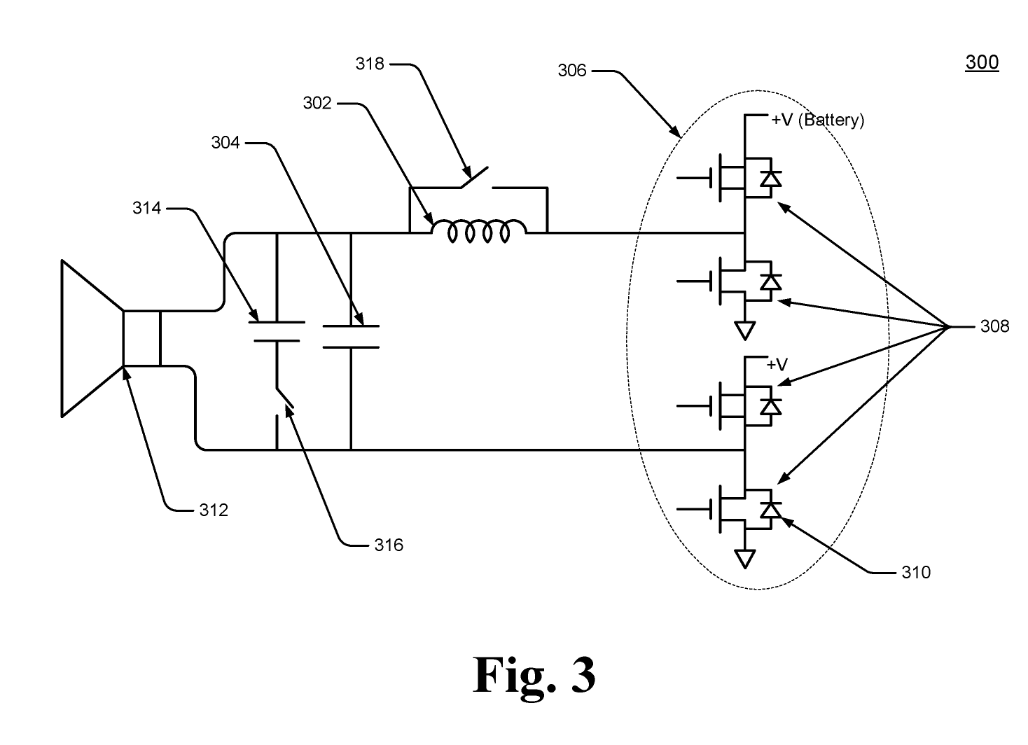

FIG. 3 illustrates an example amplification circuit 300. The example amplification circuit 300 can be used as part of the example mobile audio device 100. As noted, by using the techniques and devices that implement acoustic power coupling for mobile audio devices, a force (e.g., the high-frequency pressure wave 216 of FIG. 2) can be applied to a speaker (e.g., device speaker 106 of FIG. 1) to produce an AC voltage across the amplification circuit 300 (e.g., the amplification circuit 104 of FIG. 1).

As shown in FIG. 3, the example amplification circuit 300 is a class-D amplifier circuit that includes a filter inductor 302, a filter capacitor 304, an H-bridge circuit 306, and a device speaker 312. The device speaker 312 can be any of a variety of speaker types (e.g., the example device speaker 202 or the example device speaker 204 as described with reference to FIG. 2). The filter inductor 302 and the filter capacitor 304 provide a low-pass filter to reduce high frequency electromagnetic interference when the class-D amplifier circuit 300 is operating to drive the device speaker 312 and produce sound.

The H-bridge circuit 306 is a circuit that allows a voltage to be applied across it in either direction. As shown in FIG. 3, the H-bridge circuit 306 includes four field-effect transistor (FET) elements 308. Each FET element 308 may include a body diode 310 that enables the reversible voltage (for clarity, only one of the four body diodes 310 shown on FIG. 3 is labeled). During normal operation as part of the class-D amplifier circuit 300, the FET elements 308 receive an input signal and convert it to a high-frequency waveform that can be used to drive the device speaker 312 and produce sound output. Operated in reverse (e.g., applying a voltage across the class-D amplifier circuit 300 in a direction opposite of the direction applied to produce sound output), the H-bridge circuit 306 functions as a full bridge rectifier to receive the AC voltage and convert it to provide a DC voltage to charge a battery (e.g., the rechargeable battery 102 of FIG. 1). In other implementations, the FET elements 308 may be used as a synchronous rectifier by including a controller that can turn the FET elements 308 on when their diodes are forward biased. This implementation can be more efficient than relying on the body diodes 310.

The class-D amplifier circuit 300 may also include a resonant capacitor 314 that can be used to increase the AC voltage by tuning a resonant frequency of the class-D amplifier circuit 300 to more closely match a frequency of the force that is producing the AC voltage. For example, the resonant capacitor 314 can be configured so that the AC voltage (produced by exposing the speaker 312 to a high-frequency pressure wave) provided to the H-bridge circuit 306 is at a first voltage level (e.g., at least 1 volt (V)). The class-D amplifier circuit 300 and H-bridge circuit 306 can amplify the produced voltage to a second voltage level that is greater than the first voltage level (e.g., at least 2 volts) by turning on the lowermost FET element 308 of the H-bridge circuit 306, making it function as a voltage doubler. For higher voltages, the lowermost FET element 308 can remain off (or be driven as a part of the synchronous rectifier described above) to implement the H-bridge rectifier circuit 306. Implementations of the class-D amplifier circuit 300 that include the filter inductor 302 and the resonant capacitor 314 may include a first switching element 316 that engages the resonant capacitor 314 when closed and a second switching element 318 that bypasses the filter inductor when closed. The first switching element 316 and the second switching element 318 can be any of a variety of switching elements (e.g., an electronic switch, a FET switch, a magnetic switch, a mechanical switch, an optical switch, an acoustic switch, and so forth).

As noted, the resonant capacitor 314 is used to better match the resonant frequency of the class-D amplifier circuit 300 with the frequency of the input force. In speakers that are highly dampened, (e.g., so called “Low-Q” speakers), the resonant capacitor 314 may not provide significant benefits, so the first switching element 316 is optional. Likewise, because the coil itself serves as the filter in many types of voice coil speakers, the second switching element 318 is also optional.

In some implementations, the first switching element 316 and/or the second switching element 318 are configured to close automatically when they are located within a threshold distance from a recognized source of the force and to open automatically when located outside the threshold distance. For example, the first switching element 316 and/or the second switching element 318 may be an acoustic switch that is configured to close when it detects a particular frequency of a known charging source (e.g., a source of the high-frequency pressure wave 216 of FIG. 2).

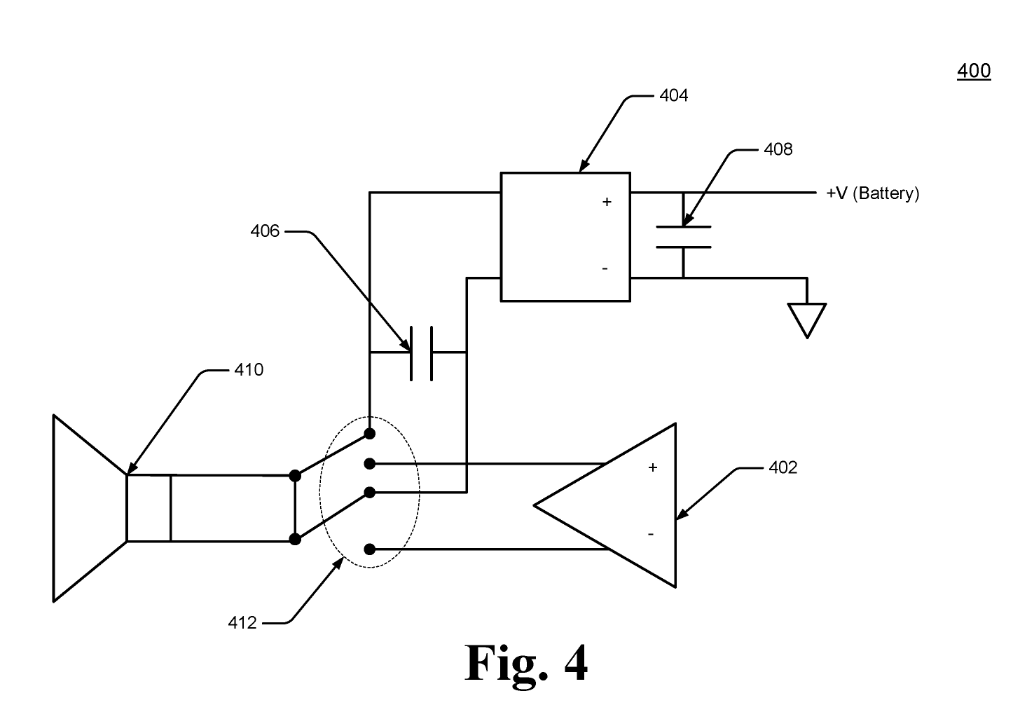

FIG. 4 illustrates another example amplification circuit 400 that can be used with a mobile audio device (e.g., the example mobile audio device 100 of FIG. 1). As noted, by using the techniques and devices that implement acoustic power coupling for mobile audio devices, a force (e.g., the high-frequency pressure wave 216 of FIG. 2) can be applied to a speaker (e.g., device speaker 106 of FIG. 1) to produce an AC voltage across the amplification circuit 400 (e.g., the amplification circuit 104 of FIG. 1).

The example amplification circuit 400 includes a power amplifier 402 (e.g., an operational amplifier), a rectifier 404, a resonant capacitor 406 that can tune a resonant frequency of the example amplification circuit 400 to match a frequency of the force, a filter capacitor 408, a device speaker 410, and a switching element 412 configured to switch an electrical connection to the device speaker 410 between the power amplifier 402 and the rectifier 404. The switching element 412 can be any of a variety of switches (e.g., a double pole double throw (DPDT) relay or a semiconductor switch).

During normal operation (not shown in FIG. 4), the switching element 412 connects the device speaker 410 with the power amplifier 402. The power amplifier 402 receives an input signal and converts it to a waveform that can be used to drive the device speaker 410 and produce sound output. In a charging mode, as shown in FIG. 4, the switching element 412 connects the device speaker 410 with the rectifier 404. The resonant capacitor 406 forms a resonant LC network with the inductance of the device speaker 410, boosting the AC voltage produced by application of the force to the device speaker 410. The increased AC voltage is applied to the rectifier 404, which converts and amplifies it to provide a DC voltage to charge a battery (e.g., the rechargeable battery 102 of FIG. 1). The rectifier 404 can be implemented in a bridge rectifier configuration or a voltage doubler configuration, as described above. The rectifier 404 can also be implemented as a passive diode rectifier or as an active synchronous rectifier, as described above.

It should be noted that the term “amplification circuit” as used in this disclosure includes any circuitry connected to a device speaker (such as device speakers 106, 202, 204, 312, or 410), regardless of whether the connected circuitry performs any amplification of a voltage or sound pressure level.

### Example Methods

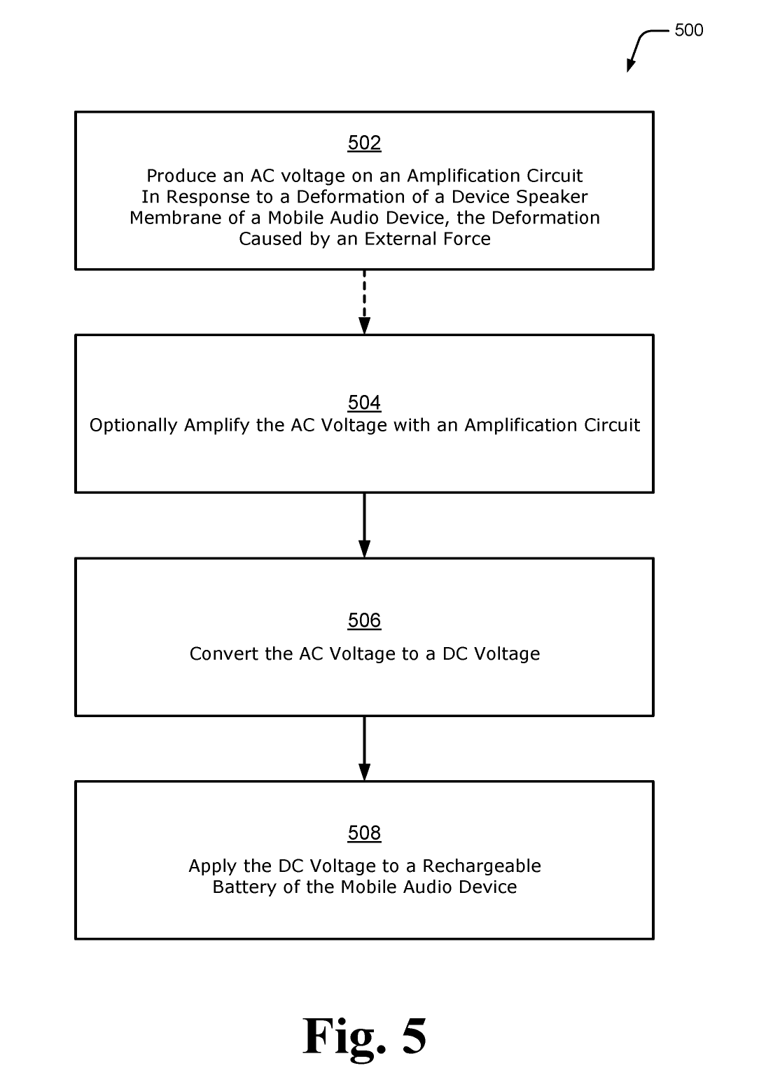

FIG. 5 illustrates an example flow chart illustrating an example process for implementing acoustic power coupling for mobile audio devices in accordance with one or more aspects.

With the structure of the example mobile audio device 100 detailed, the discussion turns to techniques for implementing acoustic power coupling for mobile audio devices. These techniques can be implemented using the previously described apparatuses and example configurations such as the example device speaker 202, the example device speaker 204, the example amplification circuit 300, and/or the example amplification circuit 400.

These techniques include methods illustrated in FIG. 5, operations of which are not necessarily limited to the orders shown. The operations can be looped, repeated, or re-ordered to implement various aspects described herein. Further, these methods may be used in conjunction with other methods, in whole or in part, whether performed by the same entity, separate entities, or any combination thereof. In portions of the following discussion, reference will be made to the example devices and circuits shown in FIGS. 1-4. Such reference is not to be taken as limiting the subject matter herein to any example configurations, but rather as illustrative of one of a variety of examples.

FIG. 5 depicts a method 500 for implementing acoustic power coupling for mobile audio devices in accordance with one or more aspects to enable wireless battery charging. The mobile audio device can be any of a variety of mobile audio devices that include a device speaker with a membrane that produces audio output for the mobile audio device, an amplification circuit electrically connected to the device speaker, and a rechargeable battery electrically connected to the amplification circuit (e.g., the example mobile audio device 100).

At 502, an alternating (AC) voltage is produced on the amplification circuit. The AC voltage is produced in response to a deformation of the membrane of the device speaker caused by a force from a force generator. The configuration of the membrane can vary, and an orientation of the membrane while exposed to the force may be adjusted so that the orientation is effective to enable more efficient energy transfer from the force generator to the membrane. In other modes of operation, the membrane of the device speaker also produces audio output for the mobile audio device in response to a signal from the amplification circuit.

As noted, the force can be applied in various forms. For example, the force may be a pressure wave applied from a distance away from the membrane. The pressure wave may be an ultrasonic pressure wave (i.e., have a frequency above 20 kilohertz (KHz)). In other implementations, the frequency of the pressure wave may be at or below 20 KHz. The magnitude of the force may also vary, depending on the configuration of the device speaker 106 and the amplification circuit 104.

At 504, the amplification circuit optionally amplifies the AC voltage. In some implementations, the amplification circuit is a class-D amplifier circuit that includes a filter inductor, a filter capacitor, a first switching element, and a second switching element. The filter inductor and the filter capacitor provide a low-pass filter to reduce high frequency electromagnetic interference when the class-D amplifier circuit is operating to drive the device speaker and produce sound. Additionally or alternatively, the class-D amplifier circuit may include a resonant capacitor configured to amplify the AC voltage provided to the amplification circuit by tuning a resonant frequency of the class-D amplifier circuit to match a frequency of the force.

The switching elements may be any of a variety of types of switches (e.g., FET switches, magnetic switches, mechanical switches, optical switches, acoustic switches, and so forth) and closing the first switching element engages the resonant capacitor and closing the second switching element bypasses the filter inductor. In implementations, the first switching element and the second switching element are closed automatically when the first switching element and the second switching element are located within a threshold distance from the force generator and opened automatically when the first switching element and the second switching element are located outside the threshold distance from the force generator. The automatic opening and closing may be controlled using various sensor and/or switches that can detect a proximity of the force generator. For instance, continuing the example above in which the force is a high-frequency pressure wave, the first and second switching elements may be acoustic switches configured to close when a particular frequency associated with the force generator is detected.

At 506, the amplification circuit converts the AC voltage to a direct (DC) voltage. Continuing the above example, the class-D amplifier circuit includes an H-bridge circuit that functions as a full bridge rectifier to receive the amplified AC voltage and convert it to output a DC voltage. At 508, the DC voltage is applied to the rechargeable battery to recharge the rechargeable battery.

### Example Systems

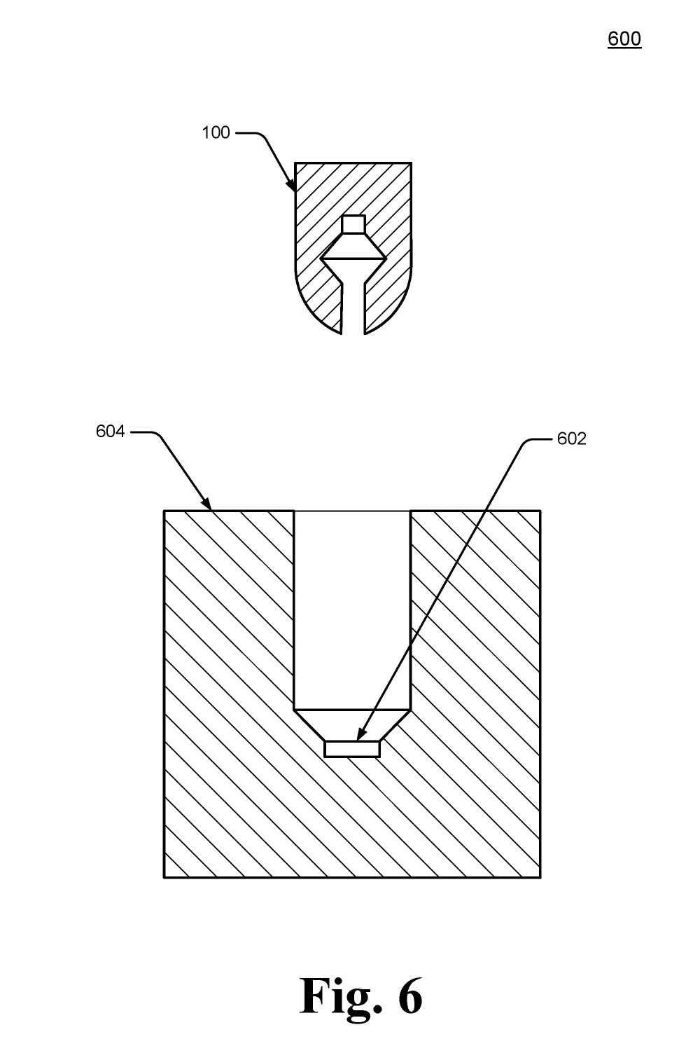

FIG. 6 illustrates an example charging system 600 in which techniques for acoustic power coupling for mobile audio devices can be implemented to enable wireless battery charging. The example charging system 600 includes a force generator 602 and a charging receptacle 604. The force generator 602 can be any of a variety of devices that can produce a force. For example, the force generator 602 may be a piezoelectric speaker or a voice coil speaker that produces a high-frequency pressure wave. The high-frequency pressure wave may be ultrasonic or have a frequency at or below 20 KHz. In other implementations, the force generator 602 may produce another kind force (e.g., a lower frequency pressure wave, a vibration force, and so forth). In various implementations, the force generator 602 may apply the force across a distance (e.g., as a pressure wave) or via direct contact (e.g., as a vibration force imparted by a vibration plate or a piston).

The charging receptacle 604 can receive a mobile audio device (e.g., the example mobile audio device 100 of FIG. 1) and orient the mobile audio device to present a speaker membrane to receive the force generated by the force generator 602. In implementations, the charging receptacle 604 provides a seal between the exterior of the mobile audio device and the interior of the charging receptacle 604 to enable an efficient energy transfer from the force generator to the membrane. The seal, along with the shape of the charging receptacle 604 also allows use of a high-powered force, such as an ultrasonic pressure wave, that can be focused to reduce losses and shield the environment outside the charging receptacle 604 from the ultrasonic pressure wave. For example, the charging receptacle 604 may provide a cavity that completely contains the speaker membrane of the mobile audio device and provides a tight seal. The charging receptacle 604 may be adjustable in order to maintain the seal while receiving mobile audio devices with different form factors and/or with different arrangements of the speaker membrane. In other implementations, the example charging system 600 may include the force generator 602 and multiple removable charging receptacles 604 that are custom shaped to receive different mobile audio devices while providing a seal that maintains efficient energy transfer.

In example implementations, the power consumed by the force generator 602 is 20 Watts (W) or less. For example, to reduce power consumption, the charging receptacle 604 and/or the force generator 602 may detect the presence of the mobile audio device and generate the force only when the mobile audio device is within a threshold distance from the charging receptacle. In this way, the force generator 602 does not consume significant power unless it is actually charging the mobile audio device. The presence of the mobile audio device may be detected with various techniques (e.g., a proximity sensor, an optical switch, a capacitive switch, an inductive switch, a magnetic switch, or an acoustic switch). For instance, the charging receptacle 604 and/or the force generator 602 may include a capacitive switch that can detect that an object has been inserted into the charging receptacle 604 and operate to power the force generator when it detects that the object has been received.

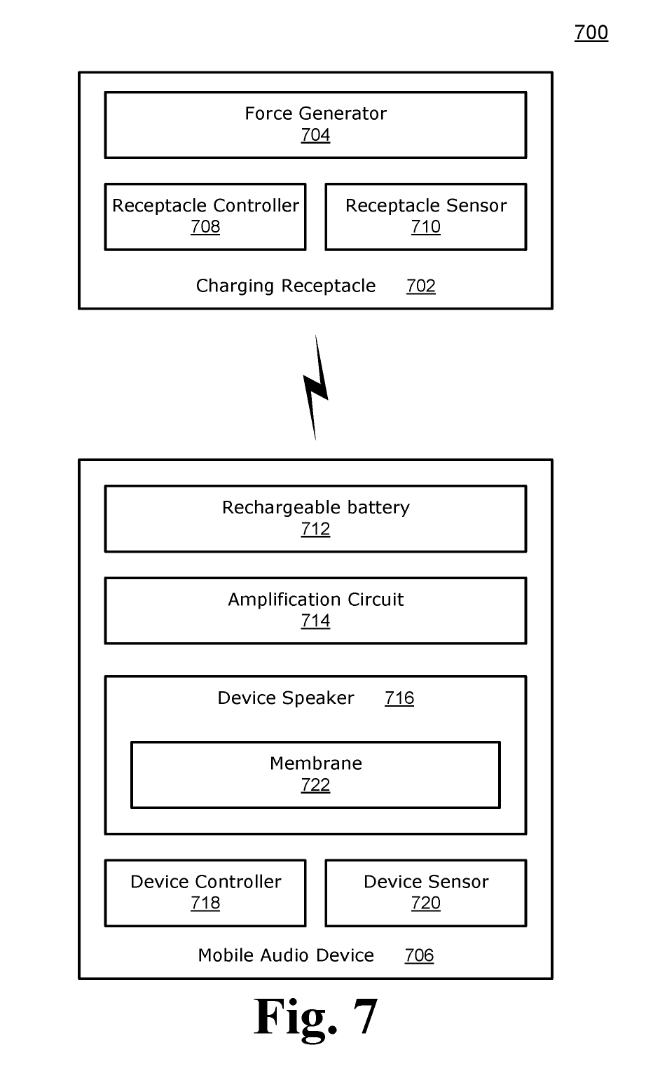

FIG. 7 is a block diagram that illustrates another example charging system 700 generally, including an example mobile audio device that is representative of one or more systems and/or devices that may implement the various techniques described herein. The example charging system 700 includes a charging receptacle 702, a force generator 704, and a mobile audio device 706. The charging receptacle 702 and the force generator 704 may be any of a variety of devices that can implement acoustic power coupling for mobile audio devices (e.g., force generator 602 and a charging receptacle 604 of FIG. 6). The mobile audio device 706 can be any of a variety of battery-powered audio output devices (e.g., a hearing aid, a wireless earbud, and so forth).

The charging receptacle 702 may also include a receptacle controller 708 and one or more receptacle sensors 710. The receptacle controller 708 and the receptacle sensors 710 are representative of components that can provide processing, communication, or analytical functionality or associated operations using hardware. The receptacle controller 708 may be a microprocessor or a microcontroller that includes memory, processors, and/or communication capability. The receptacle sensors 710 may be any of a variety of sensors such as a temperature sensor, a force transducer, an optical or capacitive switch, a proximity sensor, and so forth.

For example, the receptacle sensors 710 may include a proximity sensor or capacitive switch that can determine that the mobile audio device 706 has been inserted into the charging receptacle 702. The receptacle controller 708 can receive this status information from the receptacle sensors 710 and send a control signal to the force generator 704, causing it to generate the force. Similarly, when the receptacle sensors 710 determine that the mobile audio device 706 has been removed from the charging receptacle 702, the receptacle controller 708 can receive this status information and send another control signal to the force generator 704, causing it to stop generating the force. The receptacle controller 708 and receptacle sensors 710 may also enable other functions or operations of the charging receptacle 702, such as preset charging times, temperature-based shutoff, and so forth.

The mobile audio device 706 includes a rechargeable battery 712 that powers the mobile audio device 706, an amplification circuit 714 that is electrically connected to the rechargeable battery 712, a device speaker 716 that is electrically connected to the amplification circuit 714, a device controller 718, and one or more device sensors 720. The rechargeable battery 712 can be any of a variety of battery types (e.g., nickel-metal hydride, lithium ion, lithium ion polymer, and so forth). The device speaker 716 includes a membrane 722. The device speaker 716 can be any of a variety of speaker types (e.g., the voice coil speaker 202 or the piezoelectric speaker 204 of FIG. 2). The membrane 722 can be made from a variety of flexible materials (e.g., natural or synthetic fibers, paper-based materials, plastics, metals, and so forth).

The amplification circuit 714 can be any of a variety of amplification circuits (e.g., the example amplification circuits 300 and 400 of FIGS. 3 and 4, respectively). In at least some aspects, the amplification circuit 714 provides means for sending, receiving, and modifying signals between the various components of the mobile audio device 706 described herein. Further, in at least some aspects the device speaker 716 and the membrane 722 provide means to produce audio output for the mobile audio device 706 by deforming in response to a signal from the amplification circuit 714 or other signal-providing means. Additionally, in at least some aspects, the device speaker 716 and the membrane 722 provide means to produce an alternating (AC) voltage across the amplification circuit 714 or other signal-providing means by deforming in response to an external force (e.g., a sound pressure wave, a vibration force, and so forth). The amplification circuit 714 also amplifies the AC voltage, optionally converts the AC voltage to a direct (DC) voltage, and applies the DC voltage to the rechargeable battery 712.

The device controller 718 and the device sensors 720 are representative of components that can provide processing, communication, or analytical functionality or associated operations using hardware. The device controller 718 may be a microprocessor or a microcontroller that includes memory, processors, and/or communication capability. The device sensors 720 may be any of a variety of sensors such as a temperature sensor, a force transducer, an optical or capacitive switch, a proximity sensor, and so forth.

For example, the device sensors 720 may include a sensor that can determine a charge level of the battery of the mobile audio device 706. The device controller 718 can receive this battery level information from the device sensors 720 and send a control signal to the mobile audio device 706, causing it to generate an alert. In other implementations, the device controller 718 may be configured to communicate with the charging receptacle 702 (e.g., via receptacle controller 708) and transmit a control signal to the force generator 704 that causes it to stop generating the force when the battery is charged to an adjustable preset level. The device controller 718 and the device sensors 720 may also enable other functions or operations of the mobile audio device 706, such as preset charging times, temperature-based shutoff, and so forth.

As described with reference to FIGS. 1-6, the techniques and devices described may be enable charging the battery of a mobile audio device with high-frequency sound waves using the speaker of the mobile audio device and without requiring any additional structure or circuitry in the mobile audio device. In other implementations, however, the amplification circuit 104 may include additional features to further increase the voltage used to charge the battery. For example, a boost converter may be used to step the DC voltage before it is applied to the battery, or additional inductance circuitry may be included to increase the AC voltage provided to the amplification circuit (e.g., the H-bridge circuit 306 of FIG. 3 or the power amplifier 402 of FIG. 4). These additional components can enable voltages produced by the membrane 108 as low as 0.2V to be amplified sufficiently to be effective to charge the battery of the mobile audio device.

The described devices and techniques include a device speaker with a membrane that is moved to produce a voltage. Other mechanisms for using acoustic power coupling for mobile audio devices are also contemplated. In implementations, the example charging systems 600 and 700 may be used to charge devices that do not include speakers. For instance, a device that does include a voice coil speaker or a piezo electric speaker that are configured to produce sound output may still include a mechanism to produce vibration output (e.g., a fitness tracking device, a wrist-worn health monitor, and so forth). The example charging systems 600 and/or 700 may still allow the device to be received into a charging receptacle in an orientation that exposes the vibration producing mechanism (e.g., a piezoelectric buzzer, a pistonic motion generator, and so forth). A force generator may then expose the vibration mechanism to a force and, as described above, produce an AC voltage internal to the device that may be amplified and converted to a DC voltage usable to charge the battery of the device. In other implementations, force generator may be configured to receive sound input from various sources (e.g., a television speaker, a human voice, and so forth) and convert the sound input into a force that can be used to charge a mobile audio device, as described with respect to FIGS. 1-7.

Although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. A mobile audio device, comprising:
an amplification circuit electrically connected to a rechargeable battery configured to power the mobile audio device; and
a device speaker electrically connected to the amplification circuit and including a membrane configured to:
deform, in response to a signal from the amplification circuit, to produce audio output for the mobile audio device; and
deform, in response to a force, to produce an alternating (AC) voltage on the amplification circuit,
the amplification circuit configured to:
convert the AC voltage to a direct (DC) voltage; and
apply the DC voltage to the rechargeable battery.

2. The mobile audio device of claim 1, wherein the amplification circuit includes an H-bridge circuit configured to enable voltage to be applied in either direction across the H-bridge circuit.

3. The mobile audio device of claim 2, wherein the amplification circuit further comprises:
a filter inductor; and
a filter capacitor.

4. The mobile audio device of claim 3, wherein the amplification circuit further comprises:
a resonant capacitor that increases the produced AC voltage by tuning a resonant frequency of the amplification circuit to match a frequency of the force.

5. The mobile audio device of claim 4, wherein the amplification circuit further comprises:
a first switching element that engages the resonant capacitor when closed; and
a second switching element that bypasses the filter inductor when closed.

6. The mobile audio device of claim 4, wherein the resonant capacitor is configured to boost the produced voltage to a first voltage level and the amplification circuit is further configured to amplify the first voltage level to a second voltage level greater than the first voltage level.

7. The mobile audio device of claim 5, wherein the first switching element and the second switching element are configured to close when located within a threshold distance from a recognized source of the force and open when located outside the threshold distance.

8. The mobile audio device of claim 1, wherein the force is a pressure wave applied from a distance away from the membrane.

9. The mobile audio device of claim 8, wherein the pressure wave has a frequency above 20 kilohertz (KHz).

10. The mobile audio device of claim 8, wherein the pressure wave has a frequency at or below 20 kilohertz (KHz).

11. The mobile audio device of claim 1, wherein the force has a magnitude of at least 0.5 Pascals (Pa).

12. The mobile audio device of claim 1, wherein the amplification circuit comprises:
a power amplifier configured to provide the signal that produces audio output for the mobile audio device;
a rectifier configured to convert the AC voltage to the DC voltage;
a resonant capacitor configured to tune a resonant frequency of the amplification circuit to match a frequency of the force;
a filter capacitor; and
a switching element configured to switch an electrical connection to the device speaker between the power amplifier and the rectifier.

13. The mobile audio device of claim 1 wherein the amplification circuit is further configured to amplify the AC voltage produced by the deformation of the membrane.

14. A method for wireless battery charging in a mobile audio device that includes a device speaker with a membrane that produces audio output for the mobile audio device, an amplification circuit electrically connected to the device speaker, and a rechargeable battery electrically connected to the amplification circuit, the method comprising:
producing, in response to a deformation of the membrane caused by a force from a force generator, an alternating (AC) voltage on the amplification circuit;
converting, by the amplification circuit, the AC voltage to a direct (DC) voltage; and
applying the DC voltage to the rechargeable battery effective to recharge the rechargeable battery.

15. The method of claim 14, further comprising amplifying, by the amplification circuit, the AC voltage.

16. The method of claim 14, further comprising producing, by the membrane and in response to a signal from the amplification circuit, audio output for the mobile audio device.

17. The method of claim 14, wherein an orientation of the membrane while exposed to the force is effective to enable efficient energy transfer from the force generator to the membrane.

18. The method of claim 15, wherein amplifying the AC voltage further comprises tuning a resonant frequency of the amplification circuit to match a frequency of the force, the tuning achieved with a resonant capacitor included in the amplification circuit.

19. The method of claim 18, wherein the amplification circuit includes a filter inductor, a filter capacitor, a first switching element, and a second switching element, the method further comprising:
engaging the resonant capacitor when the first switching element is closed; and
bypassing the filter inductor when the second switching element is closed.

20. The method of claim 19, further comprising:
closing the first switching element and the second switching element when the first switching element and the second switching element are located within a threshold distance from the force generator; and
opening the first switching element and the second switching element when the first switching element and the second switching element are located outside the threshold distance from the force generator.

21. The method of claim 14, wherein the force is a pressure wave applied from a distance away from the membrane.

22. The method of claim 21, wherein the pressure wave has a frequency above 20 kilohertz (KHz).

23. The method of claim 21, wherein the pressure wave has a frequency at or below 20 kilohertz (KHz).

24. A system to enable wireless battery charging in a mobile audio device, comprising:
a force generator configured to generate a force; and
a charging receptacle configured to:
receive the mobile audio device;
orient the mobile audio device to present a speaker membrane of the mobile audio device to receive the force; and
provide a seal between an exterior of the mobile audio device and an interior of the charging receptacle to enable energy transfer from the force generator to the membrane.

25. The system of claim 24, wherein the interior of the charging receptacle is a cavity that completely contains the speaker membrane of the mobile audio device.

26. The system of claim 24, wherein;
the charging receptacle is further configured to detect a presence of the mobile audio device; and
the force generator is further configured to generate the force when the mobile audio device is within a threshold distance from the charging receptacle.

27. The system of claim 24, wherein the force is a pressure wave applied from a distance away from the membrane.

28. The system of claim 27, wherein the pressure wave has a frequency above 20 kilohertz (KHz).

29. The system of claim 27, wherein the pressure wave has a frequency at or below 20 kilohertz (KHz).

30. A mobile audio device, comprising:
a first means for sending, receiving, and modifying signals between components of the mobile audio device, the first means electrically connected to a rechargeable battery configured to power the mobile audio device; and
a second means electrically connected to the first means and configured to:
deform, in response to a signal from the first means, to produce audio output for the mobile audio device; and
deform, in response to an external force, to produce an alternating (AC) voltage across the first means,
the first means configured to:
convert the AC voltage to a direct (DC) voltage; and
apply the DC voltage to the rechargeable battery.
